(19) United States
(12) Patent Application Publication
(10) Pub. No.: US 2025/0349579 A1
(43) Pub. Date: Nov. 13, 2025

(54) CONDITION-BASED EQUIPMENT MONITORING SYSTEM – PREDICTIVE MAINTENANCE

(71) Applicant: SKYWORKS SOLUTIONS, INC., Irvine, CA (US)

(72) Inventors: Enrico Marcelo Sy, Mexicali (MX); Zelman Hernandez, Imperial, CA (US); César Mauricio Pablos Ramirez, Mexicali (MX)

(21) Appl. No.: 19/199,616

(22) Filed: May 6, 2025

Related U.S. Application Data
(60) Provisional application No. 63/644,739, filed on May 9, 2024.

(51) Int. Cl. H01L 21/67; G05B 19/418; H01L 21/66

(52) U.S. Cl. CPC H01L 21/67253; G05B 19/41865; H01L 22/20; G05B 2219/45031

(57) ABSTRACT

Aspects and embodiments disclosed herein include a system comprising a piece of semiconductor manufacturing equipment including one or more sensors configured to monitor one or more operating parameters of the piece of semiconductor manufacturing equipment, and a control system configured to receive readings regarding the one or more operating parameters from the one or more sensors and provide a warning responsive to the readings from the one or more sensors being indicative of a potential problem with the piece of semiconductor manufacturing equipment that, unless addressed outside of a regularly scheduled preventative maintenance operation for the piece of semiconductor manufacturing equipment, has a substantial likelihood of removing the piece of equipment from service for repair.

### CROSS-REFERENCE TO RELATED APPLICATIONS

This application claims priority under 35 U.S.C. § 119(e) to U.S. Provisional Patent Application Ser. No. 63/644, 739, titled “CONDITION-BASED EQUIPMENT MONITORING SYSTEM-PREDICTIVE MAINTENANCE,” filed May 9, 2024, the entire content of which is incorporated herein by reference for all purposes.

### BACKGROUND

### Field

Aspects and embodiments disclosed herein relate to systems and methods for determining whether predictive maintenance should be performed on semiconductor manufacturing, packaging, assembly, or test equipment.

### Description of Related Technology

Equipment utilized in semiconductor manufacturing, for example, dry or wet etch equipment, lithography equipment, backside grinding, diffusion or ion implantation equipment, etc., in assembly/packaging, for example, wire bond equipment, encapsulation equipment, etc., or mechanical or electrical test equipment typically undergo periodic preventative maintenance. This preventative maintenance is typically scheduled on the basis of time, for example, a weekly preventative maintenance operation, a monthly preventive maintenance operation, etc., or on the basis of a number of units processed, for example, a number of semiconductor wafers processed or a number of die having undergone wire bonding or being packaged or encapsulated.

### SUMMARY

In accordance with one aspect, there is provided a system comprising a piece of semiconductor manufacturing equipment including one or more sensors configured to monitor one or more operating parameters of the piece of semiconductor manufacturing equipment, and a control system configured to receive readings regarding the one or more operating parameters from the one or more sensors and provide a warning responsive to the readings from the one or more sensors being indicative of a potential problem with the piece of semiconductor manufacturing equipment that, unless addressed outside of a regularly scheduled preventative maintenance operation for the piece of semiconductor manufacturing equipment, has a substantial likelihood of removing the piece of equipment from service for repair.

In some embodiments, the one or more sensors include one or more of a temperature sensor, vibration sensor, particle sensor, noise level sensor, humidity sensor, photosensor, power level sensor, electrical ground connection sensor, magnetic sensor, radio frequency energy sensor, pressure sensor, strain sensor, volatile organic compound sensor, or chemical-specific sensor.

In some embodiments, the control system includes a controller internal to the piece of semiconductor manufacturing equipment.

In some embodiments, the control system further includes an external monitor configured to receive signals indicative of values of one or more parameters measured by the one or more sensors from the controller.

In some embodiments, the external monitor includes a user interface configured to display the values of the one or more parameters.

In some embodiments, the external monitor is configured to provide an indication of whether the values of the one or more parameters are outside of an acceptable range in the user interface.

In some embodiments, the external monitor is configured to provide an indication of whether the values of the one or more parameters are exhibiting an unacceptable trend in the user interface.

In some embodiments, the external monitor is configured to provide an indication of whether the values of the one or more parameters are exhibiting an unexpected combination of different parameter values in the user interface.

In some embodiments, the controller is configured to provide the signals indicative of the values of the one or more parameters to the external monitor on a continuous basis.

In some embodiments, the controller is configured to provide the signals indicative of the values of the one or more parameters to the external monitor on a periodic basis.

In some embodiments, the controller is configured to provide the signals indicative of the values of the one or more parameters to the external monitor only when the values of one or more parameters are outside of an acceptable range.

In accordance with another aspect, there is provided a method of operating a piece of semiconductor manufacturing equipment. The method comprises monitoring one or more operating parameters of the piece of semiconductor manufacturing equipment with one or more sensors associated with the piece of semiconductor manufacturing equipment, and receiving readings regarding the one or more operating parameters from the one or more sensors at a control system, the control system providing a warning responsive to the readings from the one or more sensors being indicative of a potential problem with the piece of semiconductor manufacturing equipment that should be addressed outside of a regularly scheduled preventative maintenance operation for the piece of semiconductor manufacturing equipment.

In some embodiments, the one or more sensors include one or more of a temperature sensor, vibration sensor, particle sensor, noise level sensor, humidity sensor, photosensor, power level sensor, electrical ground connection sensor, magnetic sensor, radio frequency energy sensor, pressure sensor, strain sensor, volatile organic compound sensor, or chemical-specific sensor.

In some embodiments, the control system includes a controller internal to the piece of semiconductor manufacturing equipment.

In some embodiments, the method further comprises receiving signals indicative of values of one or more parameters measured by the one or more sensors from the controller at an external monitor disposed external to the piece of semiconductor manufacturing equipment.

In some embodiments, the method further comprises displaying the values of the one or more parameters in a user interface of the external monitor.

In some embodiments, the method further comprises providing an indication of whether the values of the one or more parameters are outside of an acceptable range in the user interface.

In some embodiments, the method further comprises providing an indication of whether the values of the one or more parameters are exhibiting an unacceptable trend in the user interface.

In some embodiments, the method further comprises providing an indication of whether the values of the one or more parameters are exhibiting an unexpected combination of different parameter values in the user interface.

In some embodiments, the controller provides the signals indicative of the values of the one or more parameters to the external monitor on a continuous basis.

In some embodiments, the controller provides the signals indicative of the values of the one or more parameters to the external monitor on a periodic basis.

In some embodiments, the controller provides the signals indicative of the values of the one or more parameters to the external monitor only when the values of one or more parameters are outside of an acceptable range.

### BRIEF DESCRIPTION OF THE DRAWINGS

FIG. 1 schematically illustrates a system in accordance with the present disclosure; and

FIG. 2 is a flowchart of a method in accordance with the present disclosure.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Preventative maintenance is typically performed on semiconductor manufacturing equipment (the term “semiconductor manufacturing equipment” including wafer processing as well as die bonding, packaging, and test equipment, unless the context indicates otherwise) at set intervals of time or after a set number of processing units (wafers or die) have been processed in or using the semiconductor manufacturing equipment. Preventative maintenance activities may include cleaning or replacement of parts of the equipment, lubrication of moving parts, replacing chemicals, for example, etch or cleaning chemicals in wet etching or cleaning equipment, replacing targets in physical vapor deposition equipment, checking and/or adjusting temperature or power calibrations, re-tightening ground or power leads, and/or checking and/or adjusting alignment of portions of the equipment, among other activities. Some preventative maintenance activities may be performed on a more frequent basis, for example, once per day, once per week, or after X processing units, while other preventative maintenance activities may be performed on a less frequent basis, for example, once per month, once per year, or after Y processing units, Y>X. The operating performance of semiconductor manufacturing equipment may be periodically checked, for example, by running test wafers through a piece of equipment to check parameters such as etch rates for etching equipment or particles deposited on the test wafer when passing through the equipment. The quality of wire bonds created in wire bonding equipment may be periodically visually inspected or tested by checking stress that would result in a bond failure. Encapsulation of packaged die may be periodically visually inspected for defects such as voids. Semiconductor manufacturing equipment, however, typically does not include sensors that may provide indications of potential equipment problems or that may provide an indication that service should be performed in advance of a scheduled preventive maintenance operation (or that a scheduled preventative maintenance operation may not be needed when scheduled and could be delayed).

Aspects and embodiments disclosed herein include systems and methods that provide for predictive maintenance that may include among other things, for previously unpredictable equipment failures or unscheduled maintenance occurrences being warranted to be predictable, giving maintenance personnel a chance to prepare for a scheduled downtime and/or order parts or replacement parts in advance. In accordance with some aspects and embodiments, systems and methods disclosed herein may perform condition-based monitoring that utilizes various sensors to provide meaningful insights into the present health condition of the equipment and uses advanced analytics to predict impending failures, allowing maintenance to be scheduled and preventing the occurrence of critical failures before they actually happen. Benefits of aspects and embodiments disclosed herein include that they may use a variety of sensors and analytical software that may be integrated into the current equipment status monitoring systems as an alert and warning system to be able to anticipate the occurrence of equipment failures in the future and to schedule maintenance activities to prevent such failures.

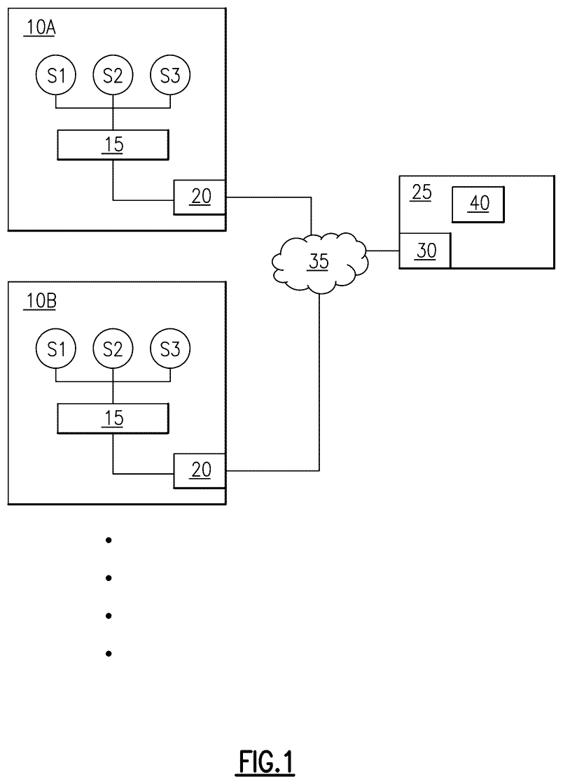

One embodiment of a system as disclosed herein is illustrated schematically in FIG. 1. The system includes one or more pieces of semiconductor manufacturing equipment. Two pieces of semiconductor manufacturing equipment, 10A and 10B (hereinafter semiconductor manufacturing equipment 10), are illustrated, however, any number of pieces of semiconductor manufacturing equipment may be present. One or more of the pieces of semiconductor manufacturing equipment may be the same type of equipment as another of the pieces of semiconductor manufacturing equipment or may be different. The semiconductor manufacturing equipment 10 may be any form of semiconductor manufacturing equipment referenced above or that one of ordinary skill in the art would expect to find in a semiconductor manufacturing plant, a semiconductor testing plant, or a semiconductor assembly or packaging plant. Each piece of semiconductor manufacturing equipment 10 may include one or more sensors S1, S2, and S3 (hereinafter sensors S). Although three sensors S are illustrated, different pieces of semiconductor manufacturing equipment 10 may include fewer or a greater number of sensors. Sensors S may be any of temperature sensors, vibration sensors, airborne or wafer or die surface particle sensors, noise level sensors, humidity sensors, photosensors, power level sensors, electrical ground connection sensors, magnetic sensors, radio frequency energy sensors, pressure sensors, strain sensors, volatile organic compound (VOC) sensors, chemical-specific sensors, or any other form of sensor that may be useful in providing an indication of an operating parameter of interest of the semiconductor manufacturing equipment 10.

The sensors S may measure operating parameters of the semiconductor manufacturing equipment 10 and communicate signals representative of the measured values of the operating parameters to a controller 15. The controller 15 may be a computerized controller. The controller may be a specially programmed general purpose computer running a Windows, macOS, or Linux operating system, may be a microcontroller such as an Arduino® microcontroller or programmable logic controller (for example, an Arduino® Portenta H7 system), an application specific integrated circuit, or any other form of electronic controller known in the art. The controller 15 may be disposed within the semiconductor manufacturing equipment 10 as illustrated or may be located distal from the semiconductor manufacturing equipment 10. The semiconductor manufacturing equipment 10 may include an input/output (I/O) port 20 (or simply an output port) for communicating data from the sensors S, either raw sensor data or data processed by the controller 15, to an external system. The I/O port 20 may be communicatively connected to a network 35 by a wired or wireless connection. If wireless, the connection between the I/O port 20 and network may be by Bluetooth® wireless communications, a cellular connection, a Wi-Fi connection, a LoRa™ communications connection, a LoRaWAN communications connection, a LoRaMesh communications connection, or any other form of wireless connection known in the art. The network 35 may be a local area network (LAN), wide area network (WAN), or a public network such as the internet. The sensor data may be communicated through the network 35 to an external monitor/controller 25 through an I/O port 30 (or simply an input port) of the external monitor/controller 25. The external monitor/controller 25 may further process the sensor data or process the raw sensor data if not previously processed by the controller 15 to produce human readable readings from the sensor data. The external monitor/controller 25 may include a user interface 40 to display the processed sensor data to a user.

In some embodiments the controller 15 and/or external monitor/controller 25 may compare the sensor data to expected values or to upper and/or lower control limits, or analyze the sensor data for trends to determine if the sensor data may be indicative of a present, potential, or imminent problem with the semiconductor manufacturing equipment 10. In some embodiments control limits may be determined from previous sensor parameter data. Control limits may be set at the median ±3σ of historic readings for a parameter. A trend of more than 4 or 5 data points of a parameter headed upward or downward in value may be indicative of the present, potential, or imminent problem with the semiconductor manufacturing equipment 10. Other statistical process control methodologies known to those of ordinary skill in the art may also be used to determine what patterns in sensor data values may be indicative of the present, potential, or imminent problem with the semiconductor manufacturing equipment 10. A warning may be provided through the user interface 40 if one or more sensor readings from one or more of the pieces of semiconductor manufacturing equipment 10 are indicative of the present, potential, or imminent problem with the semiconductor manufacturing equipment 10. A warning may also be provided through the user interface 40 if the controller 15 and/or external monitor/controller 25 detects a combination of different parameter values that is unusual or unexpected (a novelty error). The user may troubleshoot the semiconductor manufacturing equipment 10 for a problem that may have resulted in the warning or to the sensor data being outside its control limits, trending in a manner indicative of the present, potential, or imminent problem, or that may have resulted in the novelty error.

In some embodiments, sensor data may be obtained from individual sensors S continuously, or alternatively, at a periodic rate, for example, once every 10 second, once per minute, once per hour, or at another rate appropriate for monitoring a particular operating parameter. In some embodiments data may be obtained from one or more sensors continuously and from one or more other sensors in the semiconductor manufacturing equipment 10 at a periodic rate. In some embodiments, sensor data is processed at the controller 15 and data/warnings are only sent to the external monitor/controller 25 if the sensor data is indicative of the present, potential, or imminent problem with the semiconductor manufacturing equipment 10. The values of the parameters measured by the sensors S may be displayed in the user interface as absolute values relative to expected values and/or upper and/or lower control limits, in one or more trend charts, control charts, or other useful form of visualization. In some embodiments sensor data is stored in the controller 15 and/or external monitor/controller 25 so that a user may review trends in the sensor data over a desired period of time, for example, over the last day, week, month, year, or other selected period of time.

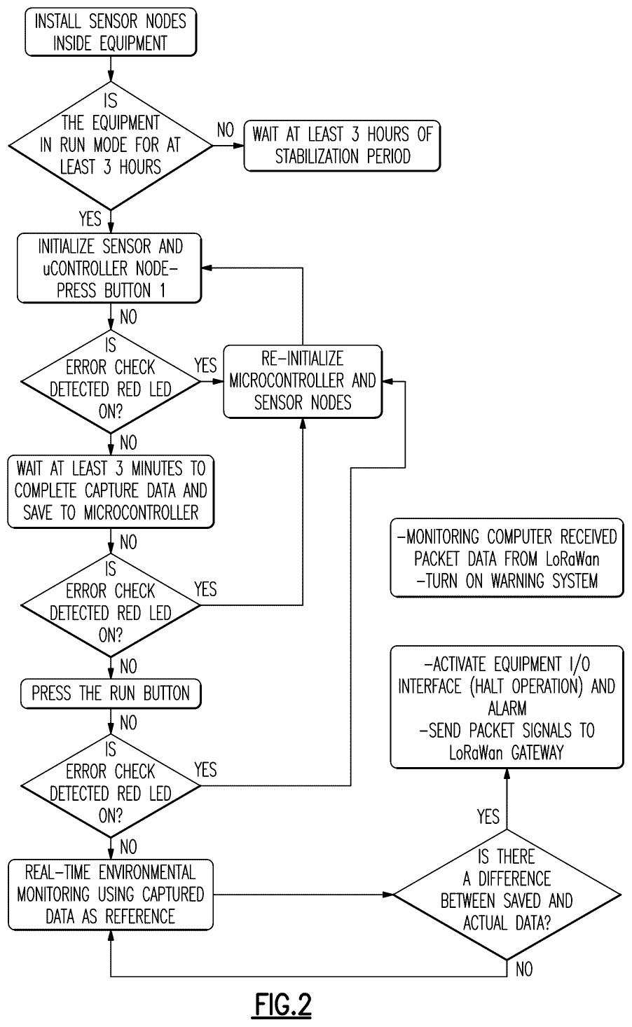

In some embodiments a method of initializing and monitoring a sensor may follow the flowchart illustrated in FIG. 2. In this flowchart it is assumed that the sensor is monitored by controller 15 including an Arduino® Portenta H7 system that communicates with an external monitor/controller computer 25 through a LoRaWAN protocol, although in other embodiments, a different form of controller 15 and/or communication protocol may be utilized. The method generally includes the following acts:
1. Initialize sensors (for example, Temperature, Vibration, VOC, Transient Voltage, Noise, etc.)
2. Condition sensors for stabilization period
3. Error Check: Ensure sensor readings are within expected ranges
   If error detected:
      Log error
      Attempt to re-initialize sensors
      If re-initialization fails, enter safe mode and signal for maintenance
4. Wait for the first button press
5. On first button press: This is a protected and hidden switch that will be used only on initial installation or resetting of the sensor reference.
   Capture sensor data—get the average information for at least 3 minutes.
   Save captured data as reference on the edge
   Error Check: Verify data capture and storage
      if error detected:
         Log error
         Signal capture failure—Red LED ON otherwise, Green LED is ON
         Retry capture process
6. Wait for the second button press
7. On second button (RUN) press:
   Use saved reference data
   Check for changes in environmental properties to determine if outside control limits
   Error Check: Ensure reference data is correctly applied
      If error detected:
         Log error
         Signal processing failure
         Halt operation and request system check
8. If variance/anomaly is detected, execute appropriate response/actions:
   activate equipment I/O for halt or pause operation.
   Send Packet signals to the LoRa gateway with ID.
   send complete environmental information Passed and Failed data.
9. Monitoring PC receives a packet of signal(s) through a LoRaWan gateway.
   Identify equipment through ID.
   Display the Packet data: Environmental data both Passed and Deviated data

In some specific, non-limiting examples, a data packet, originating from the sensors and/or a controller 15 associated with a piece of semiconductor manufacturing equipment and flagged by an alarm-triggering transmitter LoRa node, conveys a variety of environmental sensor data. This data can be visually represented in a clear, graphic format on a PC system that has the necessary visualization software. It can display the node transmitter's ID and categorize each data point, identifying those that meet established standards, those that do not, and any that have initiated an alarm.

For example, if the temperature and VOC readings from a piece of semiconductor manufacturing equipment have drastically increased above the baseline for the observed data, the LoRa node can transmit all the sensor data. The sensor data can be received by the LoRaWAN which in turn displays the sensor data on the PC screen for users to analyze along with the ID of the LoRa node that allows the users to identify and locate the piece of semiconductor manufacturing equipment.

### Example:

In the table below, hypothetical reference data based on historical performance for a piece of semiconductor manufacturing equipment (a reference signature of a specific piece of equipment) is compared to the hypothetical detected data:

| | Captured | | | |
|---|---|---|---|---|
| | and | Actual | Programmed | Micro- |
| Environmental | reference | Running | Upper Control | controller |
| Data | Data | Data | Limit (+20%) | Action |
| Temperature ° C. | 46.72 | 64.0046 | 56.064 | Not OK |
| Vibration m/s² | 78.44 | 79.22 | 94.128 | OK |
| VOC ug/m³ | 15,371 | 23,137 | 18,445.2 | Not OK |
| Environmental | 67.33 | 82.48 | 80.796 | Not OK |
| NOISE dB(A) | | | | |

Microcontroller action: Halt and activate Alarm of Equipment. Send data Packets to external monitor.

A user may analyze the measured parameter values shown above and conclude that there may be an issue with a motor within the piece of semiconductor manufacturing equipment that caused the temperature, vibration, and VOC levels to drastically increase above the upper control limits. A failing motor bearing and bad windings may cause the motor to produce more vibration, increase in heat, and emit VOCs from overheated oil and other materials in the motor. There may also be a high probability that servo motor drivers within the piece of semiconductor manufacturing equipment may be failing as well.

If only the temperature and VOC levels had deviated above the upper control limits, the root cause with higher probability may be the servo motor drivers and other driver boards within the piece of semiconductor manufacturing equipment.

However, if an anomaly is detected in the noise level alone, the user may conclude that there a higher probability that the motor bearings are about to fail and the rail guides within the piece of semiconductor manufacturing equipment may be misaligned.

When only the VOCs are showing higher than expected levels, the user may conclude that the power supply, servo drivers and driver boards within the piece of semiconductor manufacturing equipment have a probability of failing in the future and should be diagnosed and/or replaced in the future.

It should be appreciated that while various examples of the present disclosure may be implemented using well known computer programming languages on a typical computer, other examples may include trained learning models, for example, models utilizing machine learning or artificial intelligence. In some embodiments, for example, the external monitor/controller 25 of FIG. 1 may be programmed and configured to utilize a learning model to determine or update control limits for one or more monitored parameters of one or more pieces of semiconductor manufacturing equipment and/or determine a probability of an equipment failure based on historical data regarding the one or more monitored parameters and observed equipment issues or failures. In some examples, a trained learning model can be trained based on the characteristics of the semiconductor manufacturing equipment after maintenance to establish a baseline for one or more monitored parameters. Values of one or more of the monitored parameters at the time of, or just prior to an equipment failure may be provided to the learning model so that the learning model may become better able to predict when a particular equipment failure is likely to occur. Based on prior data regarding the one or more monitored parameters and the occurrences of equipment failures, the trained learning model may be able to determine the probability of an imminent equipment failure based upon the current values of the one or more monitored parameters. The trained learning model may issue an alarm to an operator if the probability of an imminent equipment failure exceeds a threshold, for example, greater than 20%, greater than 30%, greater than 40%, greater than 50%, or another level. Additionally, in instances in which multiple parameters are monitored the learning model may determine not only control limits for the individual monitored parameters, but may utilize historical data regarding values of the monitored parameters and instances of equipment failures to develop rules regarding combinations of values or trends in the multiple monitored parameters that are indicative of an increased probability of an imminent equipment failure and may issue an alarm to an operator if the probability of an imminent equipment failure exceeds a threshold, for example, greater than 30%, greater than 40%, greater than 50%, or another level.

Aspects and embodiments of the monitoring system disclosed herein may be enhanced with micro-machine learning/algorithms, enabling precise monitoring and assessment of environmental conditions within a piece of semiconductor manufacturing equipment. In some embodiments the monitoring system initially records the stabilized data of temperature, VOC levels, and other sensor information, establishing these readings as the normative benchmarks or “trained models.” The AI feature may continuously compare current data against these benchmarks using a linear regression model in a process called “AI-edge” because the analysis is conducted on a microcontroller associated with the semiconductor manufacturing equipment (for example, controller 15), not in a remote PC, minimizing the need for extensive algorithms/code and delays. Should there be deviations exceeding, for example, a 20% increase from these set benchmarks, the microcontroller signals potential equipment failure or environmental danger. Consequently, an alarm is triggered-halting the equipment and/or triggering an equipment alarm system. The I/O port 20, which may be or include a LoRa node, then promptly transmits this information to the I/O port 30, which may be or may include a LoRaWAN receiver in communication with the external monitor/controller 25, which may be or may include a PC, ensuring immediate alert and facilitating rapid intervention to prevent further complications.

This strategy, driven by AI, not only bolsters the monitoring system's safety and dependability but also aids in upholding ideal operational conditions by sidestepping potential uncontrolled incidents or thermal runaway phenomena, motor/gear malfunctions, smoke, or burning, and other forms of equipment component malfunctions or failures.

The inclusion of sensors for vibration and noise levels, along with temperature and VOCs, provides a comprehensive monitoring system.

One or more of the following features may be included in various embodiments of the systems and methods disclosed herein:
1. Temperature and VOC Detection: Temperature sensors detect the increase in temperature and prevent “thermal runaways.” VOC sensors detect carbon contents in the environment which may be the result of out-of-control heat dissipation in any equipment or parts.
2. Vibration and Noise Detection: Vibration sensors can detect unusual patterns that may indicate wear or damage in machinery, while noise level sensors can identify changes in sound that may signify operational issues or safety hazards.
3. Data Integration in the external monitor/controller 25: The data from all sensors (temperature, VOCs, vibration, noise) is collected and used to create a multi-dimensional dataset. This dataset is then used to train a more complex machine learning model that can detect correlations and patterns across different types of sensor data.
4. Enhanced Predictive Maintenance: By analyzing the combined received data from AI-edge, the machine learning model in the external monitor/controller 25 can then be utilized to predict potential equipment part failures or safety concerns with greater accuracy. For example, an increase in vibration or noise levels, along with a rise in temperature or VOCs, could be a stronger indicator of a problem than any single measurement alone.
5. Machine Learning Model: A model like a multivariate regression or a neural network may be employed in the external monitor/controller 25 to handle the complexity of multiple types of sensor data. The model can learn to weigh the importance of each type of data in predicting equipment health. In embodiments in which AI-edge is implemented on the controller 15, a liner regression model may be utilized to detect out-of-control conditions.

Once the model is trained in an AI-edge, it can predict the equipment's performance based on new sensor readings. In some embodiments the AI-edge enabled controller 15 may utilize a linear regression equation such as:

y=β0+β1×1+β2×2+ϵ

Where,

y is the predicted equipment condition,

x1 is one monitored variable, for example, temperature,

x2 is another monitored variable, for example, VOC levels,

β0 is the y-intercept,

β1 and β2 are the coefficients that represent the impact of each independent variable on the dependent variable,

and ϵ is the error term.

Other variables such as vibration and noise can also be included in a different linear regression model. Combining both linear regression models creates coexisting models to simplify the complexity of analysis of multiple types of sensor data in an AI edge.
6. Real-Time Monitoring and Alerts: The system can continue to monitor in real-time, comparing live data against the model's predictions. If the sensor readings deviate significantly from what the model expects (considering all types of data), it can trigger an alarm in controller 15 (which may be an AI-edge controller), and send the sensor data through I/O port 20 (which may be or may include a LoRaWAN gateway) which can then be received by the external monitor/controller 25 that analyzes the data in more detail to determine the likelihood of an equipment failure.

By leveraging machine learning with a full spectrum of sensor data, aspects and embodiments of the system and method disclosed herein becomes a powerful tool for ensuring the reliability and safety of equipment, as well as the safety of the environment and personnel in which it operates.

As the term is used herein a “substantial likelihood of removing the piece of equipment from service for repair” should be understood to mean one or more monitored parameters of the semiconductor processing equipment exceeding a control limit, or having been determined to have a probability of an imminent equipment failure exceeds a threshold as described above.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as,” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A system comprising:
a piece of semiconductor manufacturing equipment including one or more sensors configured to monitor one or more operating parameters of the piece of semiconductor manufacturing equipment; and
a control system configured to receive readings regarding the one or more operating parameters from the one or more sensors and provide a warning responsive to the readings from the one or more sensors being indicative of a potential problem with the piece of semiconductor manufacturing equipment that, unless addressed outside of a regularly scheduled preventative maintenance operation for the piece of semiconductor manufacturing equipment, has a substantial likelihood of removing the piece of equipment from service for repair.

2. The system of claim 1 wherein the one or more sensors include one or more of a temperature sensor, vibration sensor, particle sensor, noise level sensor, humidity sensor, photosensor, power level sensor, electrical ground connection sensor, magnetic sensor, radio frequency energy sensor, pressure sensor, strain sensor, volatile organic compound sensor, or chemical-specific sensor.

3. The system of claim 1 wherein the control system includes a controller internal to the piece of semiconductor manufacturing equipment.

4. The system of claim 3 wherein the control system further includes an external monitor configured to receive signals indicative of values of one or more parameters measured by the one or more sensors from the controller.

5. The system of claim 4 wherein the external monitor includes a user interface configured to display the values of the one or more parameters.

6. The system of claim 5 wherein the external monitor is configured to provide an indication of whether the values of the one or more parameters are outside of an acceptable range in the user interface.

7. The system of claim 5 wherein the external monitor is configured to provide an indication of whether the values of the one or more parameters are exhibiting an unacceptable trend in the user interface.

8. The system of claim 5 wherein the external monitor is configured to provide an indication of whether the values of the one or more parameters are exhibiting an unexpected combination of different parameter values in the user interface.

9. The system of claim 4 wherein the controller is configured to provide the signals indicative of the values of the one or more parameters to the external monitor on a continuous basis.

10. The system of claim 4 wherein the controller is configured to provide the signals indicative of the values of the one or more parameters to the external monitor on a periodic basis.

11. The system of claim 4 wherein the controller is configured to provide the signals indicative of the values of the one or more parameters to the external monitor only when the values of one or more parameters are outside of an acceptable range.

12. A method of operating a piece of semiconductor manufacturing equipment, the method comprising:
monitoring one or more operating parameters of the piece of semiconductor manufacturing equipment with one or more sensors associated with the piece of semiconductor manufacturing equipment; and
receiving readings regarding the one or more operating parameters from the one or more sensors at a control system, the control system providing a warning responsive to the readings from the one or more sensors being indicative of a potential problem with the piece of semiconductor manufacturing equipment that should be addressed outside of a regularly scheduled preventative maintenance operation for the piece of semiconductor manufacturing equipment.

13. The method of claim 12 wherein the one or more sensors include one or more of a temperature sensor, vibration sensor, particle sensor, noise level sensor, humidity sensor, photosensor, power level sensor, electrical ground connection sensor, magnetic sensor, radio frequency energy sensor, pressure sensor, strain sensor, volatile organic compound sensor, or chemical-specific sensor.

14. The method of claim 12 wherein the control system includes a controller internal to the piece of semiconductor manufacturing equipment.

15. The method of claim 14 further comprising receiving signals indicative of values of one or more parameters measured by the one or more sensors from the controller at an external monitor disposed external to the piece of semiconductor manufacturing equipment.

16. The method of claim 15 further comprising displaying the values of the one or more parameters in a user interface of the external monitor.

17. The method of claim 16 further comprising providing an indication of whether the values of the one or more parameters are outside of an acceptable range in the user interface.

18. The method of claim 16 further comprising providing an indication of whether the values of the one or more parameters are exhibiting an unacceptable trend in the user interface.

19. The method of claim 16 further comprising providing an indication of whether the values of the one or more parameters are exhibiting an unexpected combination of different parameter values in the user interface.

20. The method of claim 15 wherein the controller provides the signals indicative of the values of the one or more parameters to the external monitor on a continuous basis.
